(19) United States
(12) Patent Application Publication
(10) Pub. No.: US 2024/0364080 A1
(43) Pub. Date: Oct. 31, 2024

(54) MULTI-LAYER OXIDE APERTURE FOR A HIGH-BANDWIDTH LASER

(71) Applicant: Mellanox Technologies, Ltd., Yokneam (IL)

(72) Inventors: Filip Leonard Hjort, Gothenburg (SE); Anders Gösta Larsson, Hovas (SE); Isabelle Cestier, Haifa (IL); Elad Mentovich, Tel Aviv (IL)

(21) Appl. No.: 18/140,028

(22) Filed: Apr. 27, 2023

(51) Int. Cl. H01S 5/183

(52) U.S. Cl. CPC H01S 5/18311; H01S 5/18375

(57) ABSTRACT

Some embodiments of the present invention are directed to a multi-layer oxide aperture for a VCSEL. The oxide aperture may include multiple layers having different aluminum fractions that may reduce a spectral width of the VCSEL while maintaining longitudinal confinement. The oxide aperture may be formed from a mirror layer of the VCSEL proximate an active region. The mirror layer may include first epitaxial layers closest to the active region having a first aluminum fraction selected to longitudinally confine the optical field of the VCSEL. The mirror layer may include second epitaxial layers that have a second aluminum fraction low enough to prevent substantial oxidation of the second epitaxial layers. Additionally, the mirror layer may include third epitaxial layers that have a third aluminum fraction greater than the first and second aluminum fractions. The third epitaxial layers may be oxidized to form the oxide aperture.

### CROSS-REFERENCE TO RELATED APPLICATION

To supplement the present disclosure, this application incorporates herein by reference U.S. patent application Ser. No. ______ for a “Mode-Filtered Laser with Multi-Layer Oxide Aperture for High-Bandwidth and Side-Mode Suppression” filed concurrently herewith.

### FIELD OF THE INVENTION

The present invention relates to a multi-layer oxide aperture for a high-bandwidth laser (e.g., a vertical-cavity surface-emitting laser).

### BACKGROUND

With demand for high-speed and high-volume data communication increasing, communications providers are increasingly adopting optics-based communication solutions. To meet these demands, high-speed transmitters are being developed.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a laser including an active region configured to emit light and defining an optical axis and a mirror layer proximate the active region and disposed along the optical axis. The mirror layer may include a first portion proximate the active region having a first aluminum fraction, a second portion proximate the first portion having a second aluminum fraction that is less than the first aluminum fraction, and a third portion proximate the second portion having a third aluminum fraction that is greater than the first aluminum fraction. The second portion may be disposed between the first portion and the third portion. The aluminum in the third portion may be oxidized to include an oxide aperture.

In some embodiments, the oxide aperture may be configured to reduce a spectral width of the light emitted by the active region, and the first portion of the mirror layer may be configured to longitudinally confine an optical field of the light.

In some embodiments, the mirror layer may include a first intermediate portion between the first portion and the second portion, where the first intermediate portion has a graded aluminum fraction that decreases from the first aluminum fraction adjacent the first portion to the second aluminum fraction adjacent the second portion. Additionally, or alternatively, the mirror layer may include a second intermediate portion between the second portion and the third portion, where the second intermediate portion has a graded aluminum fraction that increases from the second aluminum fraction adjacent the second portion to the third aluminum fraction adjacent the third portion.

In some embodiments, aluminum of the first portion and the second portion may be substantially unoxidized.

In some embodiments, the first aluminum fraction may be greater than 0.6.

In some embodiments, the first aluminum fraction may be greater than 0.8.

In some embodiments, the mirror layer may include AlGaAs.

In some embodiments, the first portion may not be aligned with an electric field node.

In some embodiments, the mirror layer may reduce a spectral width of the light emitted by the active region to less than 5 modes.

In some embodiments, the first portion may have a first thickness along the optical axis of between about 30 nanometers and 80 nanometers, the second portion may have a second thickness along the optical axis of between about 5 nanometers and 15 nanometers, and the third portion may have a third thickness along the optical axis of between about 20 nanometers and 40 nanometers.

In some embodiments, a thickness along the optical axis of the oxide aperture may be substantially uniform in a direction perpendicular to the optical axis.

In some embodiments, the laser may be a vertical-cavity surface-emitting laser.

In some embodiments, the mirror layer may be a first mirror layer of a distributed Bragg reflector.

In some embodiments, the mirror layer may include a plurality of epitaxial layers, where each of the first portion, the second portion, and the third portion includes a subset of the plurality of epitaxial layers.

In another aspect, the present invention is directed to a method of manufacturing a laser. The method may include forming first epitaxial layers proximate an active region, where the active region defines an optical axis and is configured to emit light parallel to the optical axis, and where the first epitaxial layers have a first aluminum fraction. The method may further include forming second epitaxial layers proximate the first epitaxial layers, where the second epitaxial layers have a second aluminum fraction that is less than the first aluminum fraction. The method may further include forming third epitaxial layers proximate the second epitaxial layers, where the third epitaxial layers have a third aluminum fraction that is greater than the first aluminum fraction, and where the second epitaxial layers are between the first epitaxial layers and the third epitaxial layers. The method may further include oxidizing the third epitaxial layers to form an oxide aperture.

In some embodiments, the first epitaxial layers, the second epitaxial layers, and the third epitaxial layers may form at least a portion of a mirror layer of a plurality of mirror layers.

In some embodiments, the method may include, before forming the second epitaxial layers, selecting the second aluminum fraction to be low enough to prevent oxidation of the second epitaxial layers and the first epitaxial layers while oxidizing the third epitaxial layers.

In some embodiments, the method may include, before forming the first epitaxial layers, selecting the first aluminum fraction to be high enough to longitudinally confine an optical field of the light.

In some embodiments, forming the third epitaxial layers may include forming the third epitaxial layers such that the third epitaxial layers are not aligned with an electric field node.

In some embodiments, the method may include, before forming the second epitaxial layers, forming first intermediate epitaxial layers, where the first intermediate epitaxial layers are disposed between the first epitaxial layers and the second epitaxial layers, and where the first intermediate epitaxial layers have a graded aluminum fraction that decreases from the first aluminum fraction adjacent the first epitaxial layers to the second aluminum fraction adjacent the second epitaxial layers. Additionally, or alternatively, the method may include, before forming the third epitaxial layers, forming second intermediate epitaxial layers, where the second intermediate epitaxial layers are disposed between the second epitaxial layers and the third epitaxial layers, and where the second intermediate epitaxial layers have a graded aluminum fraction that increases from the second aluminum fraction adjacent the second epitaxial layers to the third aluminum fraction adjacent the third epitaxial layers.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1 illustrates a schematic cross-section of a layer structure of a laser, in accordance with an embodiment of the invention;

FIG. 2A illustrates an aluminum-content profile of a mirror layer for forming an oxide layer;

FIG. 2B illustrates a cross-section of a shape of the mirror layer of FIG. 2A after oxidation to form an oxide layer;

FIG. 2C is a graph showing a simulated effective index, transverse mode profiles, and a simulated bandwidth of a laser including the mirror layer of FIG. 2A after oxidation to form the oxide layer of FIG. 2B;

FIG. 3A illustrates an aluminum-content profile of another mirror layer for forming an oxide layer;

FIG. 3B illustrates a cross-section of a shape of the mirror layer of FIG. 3A after oxidation to form an oxide layer;

FIG. 3C is a graph showing a simulated effective index, transverse mode profiles, and a simulated bandwidth of a laser including the mirror layer of FIG. 3A after oxidation to form the oxide layer of FIG. 3B;

FIG. 4A illustrates an aluminum-content profile of another mirror layer for forming an oxide layer;

FIG. 4B illustrates a cross-section of a shape of the mirror layer of FIG. 4A after oxidation to form an oxide layer;

FIG. 4C is a graph showing a simulated effective index, transverse mode profiles, and a simulated bandwidth of a laser including the mirror layer of FIG. 4A after oxidation to form the oxide layer of FIG. 4B;

FIG. 5A illustrates an aluminum-content profile of a mirror layer for forming an oxide layer, in accordance with an embodiment of the invention;

FIG. 5B illustrates a cross-section of a shape of the mirror layer of FIG. 5A after oxidation to form an oxide layer;

FIG. 5C is a graph showing a simulated effective index, transverse mode profiles, and a simulated bandwidth of a laser including the mirror layer of FIG. 5A after oxidation to form the oxide layer of FIG. 5B; and

FIG. 6 illustrates a method for manufacturing a laser, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, demand for high-speed and high-volume data communication is increasing, and communications providers are increasingly adopting optics-based communication solutions. To meet these demands, high-speed transmitters are being developed. Such high-speed transmitters may include different types of lasers, such as light emitting diodes, top-emitting lasers, bottom-emitting lasers, edge-emitting lasers, GaAs-based lasers, InP-based lasers, directly modulated lasers, distributed-feedback lasers, and/or the like. For example, vertical-cavity surface-emitting lasers (VCSELs) may include oxide apertures for electrical current confinement and optical guiding, which increase the speeds at which VCSEL-based transmitters can operate. Such oxide apertures are typically formed by selectively, laterally oxidizing a layer of AlGaAs in a VCSEL. The thickness and position of the oxide layer influences the transverse optical guiding, which determines the spectral characteristics of the VCSEL. However, due to oxidation in the vertical direction (e.g., unavoidable oxidation), layers adjacent to the selectively oxidized layer also partly oxidize and effectively increase the thickness of oxidized layers, which, as noted, influences transverse optical guiding. The thickness of the oxidized layers and their design also impact the longitudinal guiding (e.g., optical confinement) that influences high-speed performance of the VCSEL. Therefore, there exists a trade-off between reducing the spectral width by reducing the strength of transverse optical guiding and optimizing the high-speed performance of the VCSEL when designing the oxide layers.

Some embodiments of the present invention are directed to a multi-layer oxide aperture for a VCSEL. The oxide aperture may include multiple layers having different aluminum fractions that may reduce a spectral width of the VCSEL while maintaining longitudinal confinement. In particular, the oxide aperture may be formed from a mirror layer of the VCSEL proximate an active region. The mirror layer may include first epitaxial layers closest to the active region that have a first aluminum fraction selected to longitudinally confine the optical field of the VCSEL. The mirror layer may also include second epitaxial layers above the first epitaxial layers that have a second aluminum fraction less than the first aluminum fraction. The second aluminum fraction may be selected to be low enough to prevent substantial oxidation of the second epitaxial layers (e.g., due to vertical oxidation when forming the oxide aperture). Additionally, the mirror layer may include third epitaxial layers above the second epitaxial layers that have a third aluminum fraction greater than the first and second aluminum fractions. The third epitaxial layers may be oxidized to form the oxide aperture. In some embodiments, the mirror layer may also include intermediate portions between the first epitaxial layers and the second epitaxial layers and between the second epitaxial layers and the third epitaxial layers that each have a graded aluminum fraction. As noted, the second aluminum fraction may be selected to be low enough to prevent oxidation of the second epitaxial layers during formation of the oxide aperture, which also prevents oxidation of the first epitaxial layers below that may otherwise occur during oxidation of the third epitaxial layers. As a result of this configuration, the mirror layer may be less distorted than in conventional designs and maintain strong longitudinal confinement for superior high-speed performance. Furthermore, the thin oxide aperture formed by the third epitaxial layers may reduce the spectral width of the VCSEL (e.g., to less than five modes), which reduces signal distortion allowing for high-speed transmission over longer distances.

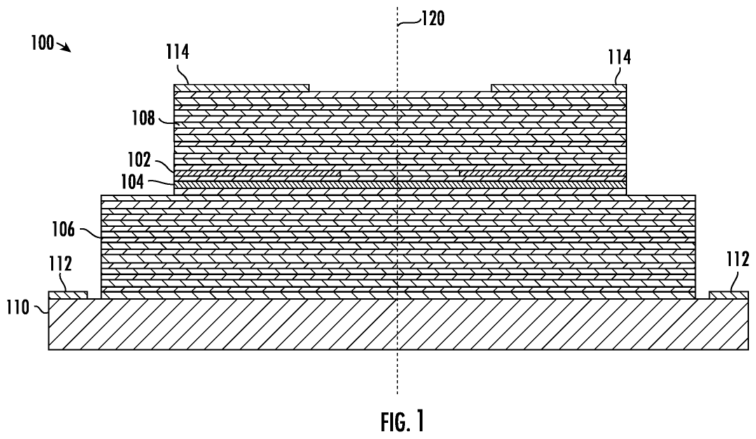

FIG. 1 illustrates a schematic cross-section of a layer structure of a laser 100, in accordance with an embodiment of the invention. In particular, the cross-section of FIG. 1 is taken in a plane that is substantially parallel to an optical axis 120 of the laser 100, where the optical axis is the nominal axis of the light emitted by the VCSEL. As shown in FIG. 1, the layer structure may include an oxide aperture 102, an active region 104, a first mirror region 106, a second mirror region 108, a substrate 110, first contacts 112, and second contacts 114. The layer structure of the laser 100 may be formed on the substrate 110.

As shown in FIG. 1, the active region 104 may be positioned between the first mirror region 106 and the second mirror region 108. The oxide aperture 102 may be formed in a mirror layer of the second mirror region 108. The active region 104 may include, for example, one or more quantum wells formed from quantum well layers.

In some embodiments, the first mirror region 106 (e.g., an n-type mirror region) and the second mirror region 108 (e.g., a p-type mirror region) may include distributed Bragg reflectors formed of multiple alternating semiconductor layers (e.g., of GaAs and AlGaAs), and they may vertically confine light generated in the active region 104. In this regard, the active region 104 may define an active region plane (e.g., a horizontal plane in the orientation of FIG. 1) and emit light parallel to the optical axis 120 of the laser 100, where the optical axis 120 is perpendicular to the active region plane.

As shown in FIG. 1, the first contacts 112 may be positioned on the substrate 110, and the second contacts 114 may be positioned on a surface (e.g., an upper surface) of the second mirror region 108. The first contacts 112 and the second contacts 114 may provide electrical contacts for driving the laser 100.

As will be appreciated by one of ordinary skill in the art in light of this disclosure, the laser 100 may include other elements, such as metal contacts, one or more trenches, one or more coatings (e.g., an anti-reflective coating and/or the like), one or more insulators, one or more lenses, and/or the like. Although the laser 100 depicted in FIG. 1 is a top-emitting VCSEL, other embodiments in accordance with the present invention may include bottom-emitting VCSELs and/or other types of VCSELs including one or more oxide apertures.

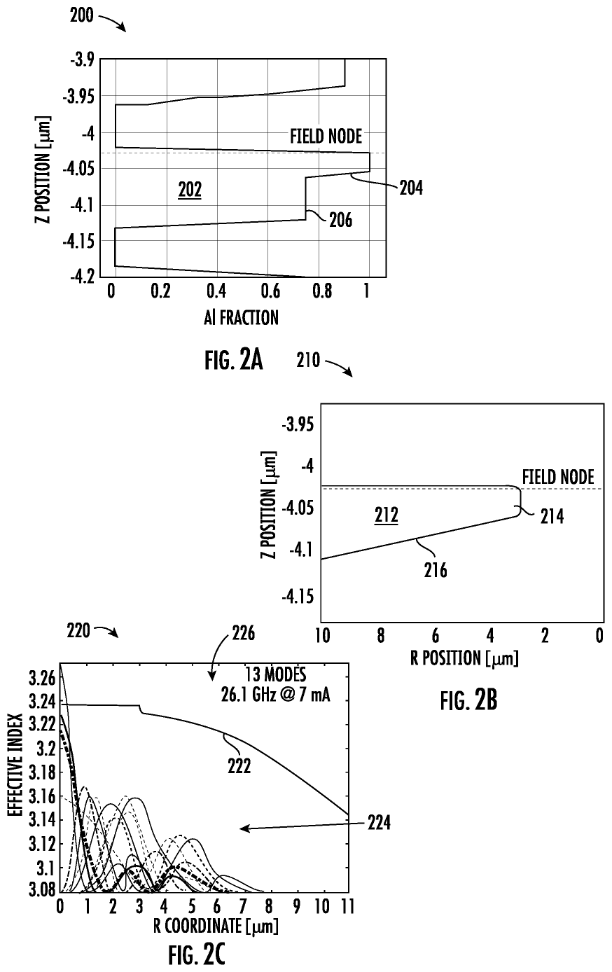

FIG. 2A illustrates an aluminum-content profile 200 of a mirror layer 202 for forming an oxide layer. The design of the mirror layer 202 may be an example of a design intended to form an oxide layer for reducing spectral width of a VCSEL. The aluminum-content profile 200 plots the aluminum fraction of the mirror layer 202 on the horizontal axis as a function of a z-position within a laser on the vertical axis. The z-position corresponds to a position within a layer structure of the laser along the z-axis, where the z-axis is substantially parallel to the optical axis of the laser, such as the optical axis 120 of the laser 100 of FIG. 1 (e.g., extending in a vertical direction in the orientation of the layer structure of the laser 100 shown and described herein with respect to FIG. 1). As noted with respect to FIG. 1, mirror regions (e.g., the first mirror region 106 and the second mirror region 108) of a VCSEL may include multiple alternating semiconductor layers. In this regard, the mirror layer 202 may be a mirror layer in such a mirror region.

FIG. 2B illustrates a cross-section 210 of a shape of the mirror layer 202 of FIG. 2A after oxidation to form an oxide layer 212. The cross-section 210 shows the position of oxidized portions of the mirror layer 202, now in the oxide layer 212, on the horizontal axis (e.g., an r position, where r corresponds to a distance from a center of the layer structure) as a function of the z-position within the oxide layer 212 on the vertical axis.

As shown in FIG. 2A, the mirror layer 202 may include an upper portion 204 and a lower portion 206, where an aluminum fraction (e.g., more than 0.9) of the upper portion 204 is greater than an aluminum fraction (e.g., about 0.75) of the lower portion 206. When the aluminum content in the upper portion 204 of the mirror layer 202 is oxidized to form the oxide layer 212, the higher aluminum fraction in the upper portion 204 readily oxidizes to form an oxidized upper portion 214 shown in FIG. 2B. However, due to incidental or unintended oxidation in the vertical direction that occurs during the oxidation of the upper portion 204, some of the aluminum content in the lower portion 206 also oxidizes to form an oxidized lower portion 216.

As shown in FIG. 2B, the oxidized lower portion 216 tapers from a thickest point at the outermost position to a thinnest point where the oxidized lower portion 216 meets the oxidized upper portion 214. The tapered shape of the oxidized lower portion 216 is due to the mirror layer 202 being oxidized from the outermost position and the lower aluminum fraction of the lower portion 206 as compared to the upper portion 204. However, the tapered shape of the oxidized lower portion 216 influences transverse optical guiding in the laser. Furthermore, because the aluminum fraction in the lower portion 206 is substantially below 0.9, the mirror layer 202 is distorted such that longitudinal confinement and high-speed performance of the laser are reduced.

FIG. 2C is a graph 220 showing a simulated effective index 222, transverse mode profiles 224, and a simulated bandwidth 226 of a laser including the mirror layer 202 of FIG. 2A after oxidation to form the oxide layer 212 of FIG. 2B. As shown by the simulated effective index 222, the tapered shape of the oxidized lower portion 216 still provides relatively strong transverse optical guiding resulting in 13 transverse modes as shown by the transverse mode profiles 224. The simulated bandwidth 226 of the laser at a current of 7 milliamps remains a relatively high 26.1 GHz.

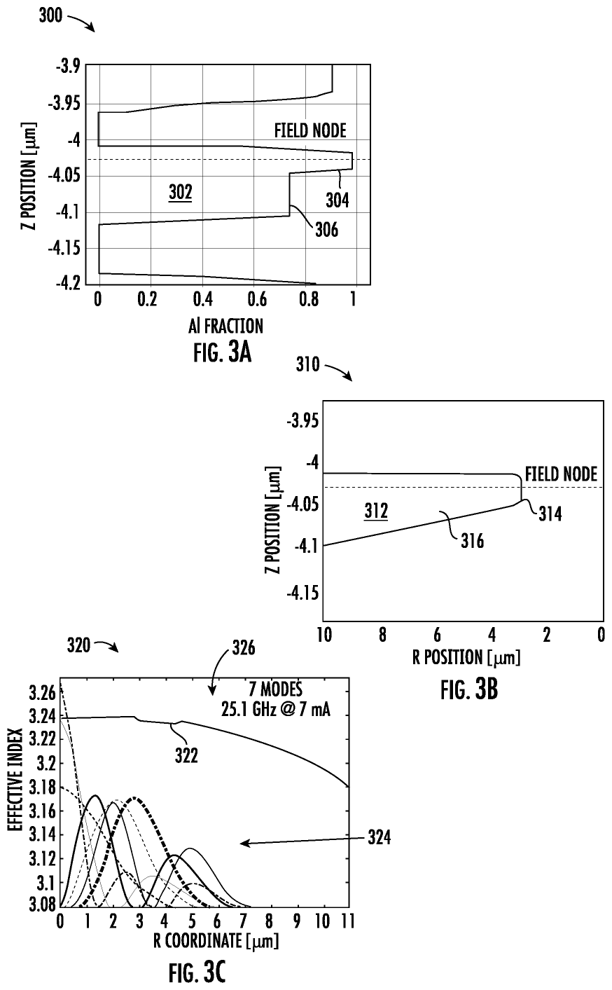

FIG. 3A illustrates an aluminum-content profile 300 of another mirror layer 302 for forming an oxide layer. The design of the mirror layer 302 may be another example of a design intended to form an oxide layer for reducing spectral width of a VCSEL. The aluminum-content profile 300 plots the aluminum fraction of the mirror layer 302 on the horizontal axis as a function of a z-position within a laser on the vertical axis. The z-position corresponds to a position within a layer structure of the laser along the z-axis, where the z-axis is substantially parallel to the optical axis of the laser, such as the optical axis 120 of the laser 100 of FIG. 1 (e.g., extending in a vertical direction in the orientation of the layer structure of the laser 100 shown and described herein with respect to FIG. 1). The mirror layer 302 may be a mirror layer in a mirror region of a VCSEL (e.g., similar to the laser 100 of FIG. 1).

FIG. 3B illustrates a cross-section 310 of a shape of the mirror layer 302 of FIG. 3A after oxidation to form an oxide layer 312. The cross-section 310 shows the position of oxidized portions of the mirror layer 302, now in the oxide layer 312, on the horizontal axis (e.g., an r position, where r corresponds to a distance from a center of the layer structure) as a function of the z-position within the oxide layer 312 on the vertical axis.

The mirror layer 302 is similar to the mirror layer 202 shown and described herein with respect to FIGS. 2A-2C. However, as shown by comparing FIGS. 2A and 3A or 2B and 3B, the oxide layer 312 is shifted to be aligned with a field node (e.g., an electric field node) by distorting the mirror.

As shown in FIG. 3A, the mirror layer 302 may include an upper portion 304 and a lower portion 306, where an aluminum fraction (e.g., more than 0.9) of the upper portion 304 is greater than an aluminum fraction (e.g., less than 0.8) of the lower portion 306. When the aluminum content in the upper portion 304 of the mirror layer 302 is oxidized to form the oxide layer 312, the higher aluminum fraction in the upper portion 304 readily oxidizes to form an oxidized upper portion 314 shown in FIG. 3B. However, due to incidental or unintended oxidation in the vertical direction that occurs during the oxidation of the upper portion 304, some of the aluminum content in the lower portion 306 also oxidizes to form an oxidized lower portion 316 having a tapered shape as described herein with respect to FIGS. 2A and 2B. Again, such a tapered shape of the oxidized lower portion 316 influences transverse optical guiding in the laser. Furthermore, because the aluminum fraction in the lower portion 306 is substantially below 0.9, the mirror layer 302 is distorted such that longitudinal confinement and high-speed performance of the laser are reduced.

FIG. 3C is a graph 320 showing a simulated effective index 322, transverse mode profiles 324, and a simulated bandwidth 326 of a laser including the mirror layer 302 of FIG. 3A after oxidation to form the oxide layer 312 of FIG. 3B. As shown by the simulated effective index 322, the tapered shape of the oxidized lower portion 316 and shifting the oxide layer 312 to align with the field node still provides relatively strong transverse optical guiding resulting in 7 transverse modes as shown by the transverse mode profiles 324. However, the simulated bandwidth 326 of the laser at a current of 7 milliamps is reduced to 25.1 GHz as compared to the 26.1 GHz of FIG. 2C. Thus, shifting the oxide layer 312 to align with the field node provides moderate reduction in the number of transverse modes but also incurs a 1 GHz reduction in bandwidth.

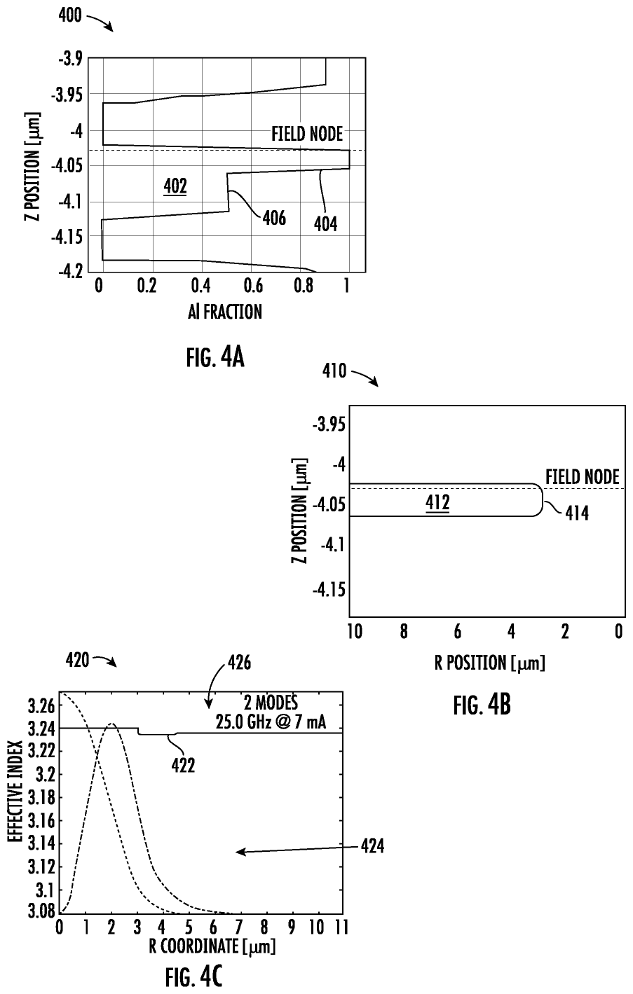

FIG. 4A illustrates an aluminum-content profile 400 of another mirror layer 402 for forming an oxide layer. The design of the mirror layer 402 may be another example of a design intended to form an oxide layer for reducing spectral width of a VCSEL. The aluminum-content profile 400 plots the aluminum fraction of the mirror layer 402 on the horizontal axis as a function of a z-position within a laser on the vertical axis. The z-position corresponds to a position within a layer structure of the laser along the z-axis, where the z-axis is substantially parallel to the optical axis of the laser, such as the optical axis 120 of the laser 100 of FIG. 1 (e.g., extending in a vertical direction in the orientation of the layer structure of the laser 100 shown and described herein with respect to FIG. 1). The mirror layer 402 may be a mirror layer in a mirror region of a VCSEL (e.g., similar to the laser 100 of FIG. 1).

FIG. 4B illustrates a cross-section 410 of a shape of the mirror layer 402 of FIG. 4A after oxidation to form an oxide layer 412. The cross-section 410 shows the position of oxidized portions of the mirror layer 402, now in the oxide layer 412, on the horizontal axis (e.g., an r position, where r corresponds to a distance from a center of the layer structure) as a function of the z-position within the oxide layer 412 on the vertical axis.

The mirror layer 402 is similar to the mirror layer 202 shown and described herein with respect to FIGS. 2A-2C. However, as shown by comparing FIGS. 2A and 4A, the mirror layer 402 includes a lower portion 406 having a lower aluminum fraction (e.g., about 0.5) than the lower portion 206 of the mirror layer 202, which has an aluminum fraction of, for example, about 0.75. As a result, and as shown in FIG. 4B, the oxide layer 412 includes an oxidized upper portion 414 and does not include an oxidized lower portion having a tapered shape, such as the oxidized lower portion 216 of FIG. 2B.

FIG. 4C is a graph 420 showing a simulated effective index 422, transverse mode profiles 424, and a simulated bandwidth 426 of a laser including the mirror layer 402 of FIG. 4A after oxidation to form the oxide layer 412 of FIG. 4B. As shown by the simulated effective index 422, the narrow shape of the oxidized upper portion 414 provides relatively weak transverse optical guiding and reduces the spectral width to 2 transverse modes as shown by the transverse mode profiles 424. However, the simulated bandwidth 426 of the laser at a current of 7 milliamps is reduced to 25.0 GHz as compared to the 26.1 GHz of FIG. 2C due to the larger distortion of the mirror layer 402 as compared to the mirror layer 202. Such distortion is due to the lower aluminum fraction in the mirror layer 402 as compared to the mirror layer 202, which as noted reduces longitudinal confinement and high-speed performance of the laser. Thus, including a lower portion 406 having a lower aluminum fraction provides significant reduction in the number of transverse modes but also incurs a 1.1 GHz reduction in bandwidth.

As will be appreciated by one of ordinary skill in the art in view of this disclosure, the 1.1 GHz reduction in bandwidth may be attributed to weakened longitudinal confinement due to the lower aluminum fraction in the lower portion 406 of the mirror layer 402. In other words, reducing the aluminum fraction in the lower portion of the mirror layer reduces the ability of the mirror layer to longitudinally confine the optical field of the light in the laser, which reduces the maximum bandwidth of the laser.

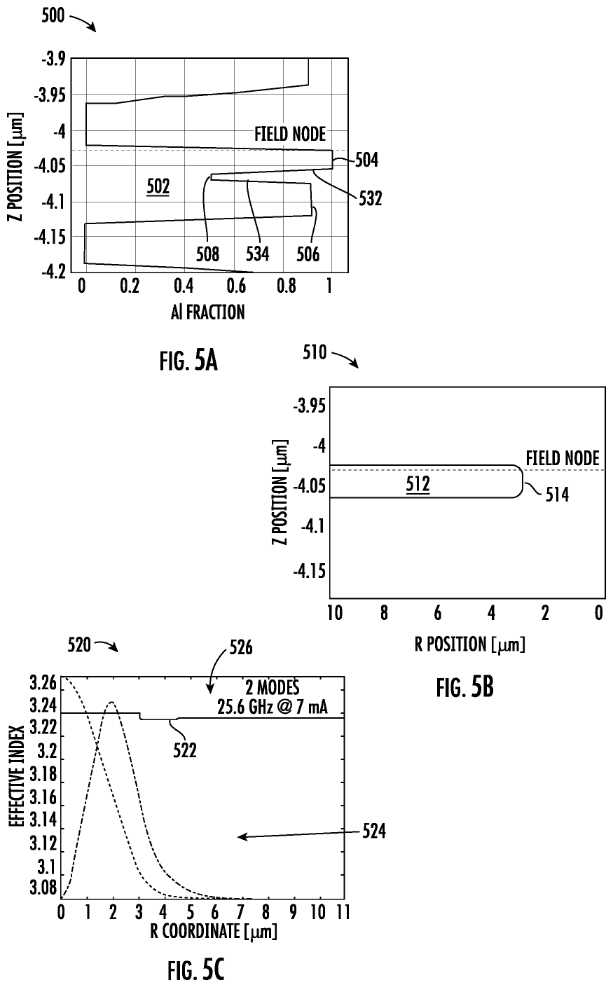

FIG. 5A illustrates an aluminum-content profile 500 of a mirror layer 502 for forming an oxide layer, in accordance with an embodiment of the invention. The aluminum-content profile 500 plots the aluminum fraction of the mirror layer 502 on the horizontal axis as a function of a z-position within a laser on the vertical axis. The z-position corresponds to a position within a layer structure of the laser along the z-axis, where the z-axis is substantially parallel to the optical axis of the laser, such as the optical axis 120 of the laser 100 of FIG. 1 (e.g., extending in a vertical direction in the orientation of the layer structure of the laser 100 shown and described herein with respect to FIG. 1). The mirror layer 502 may be a mirror layer formed from epitaxial layers in a mirror region of a VCSEL (e.g., similar to the laser 100 of FIG. 1). In some embodiments, the mirror layer 502 may include AlGaAs.

FIG. 5B illustrates a cross-section 510 of a shape of the mirror layer 502 of FIG. 5A after oxidation to form an oxide layer 512. The cross-section 510 shows the position of oxidized portions of the mirror layer 502, now in the oxide layer 512, on the horizontal axis (e.g., an r position, where r corresponds to a distance from a center of the layer structure) as a function of the z-position within the oxide layer 512 on the vertical axis.

As shown in FIG. 5A, the mirror layer 502 may include an upper portion 504, a lower portion 506, and a middle portion 508. The lower portion 506 may be proximate an active region of the laser. The middle portion 508 may be proximate the lower portion 506, and the upper portion 504 may be proximate the middle portion 508. In other words, the middle portion 508 may be disposed between the lower portion 506 and the upper portion 504.

As shown in FIG. 5A, an aluminum fraction (e.g., more than 0.9) of the upper portion 504 may be greater than an aluminum fraction of both the lower portion 506 and the middle portion 508. The lower portion 506 may have a greater aluminum fraction (e.g., about 0.9) than the middle portion 508, which may have an aluminum fraction of, for example, about 0.5. Furthermore, the lower portion 506 of the mirror layer 502 of FIG. 5A may have a greater aluminum fraction than the lower portions of conventionally designed mirror layers (e.g., the mirror layers 202, 302, and 402 of FIGS. 2A, 3A, and 4A). In some embodiments, the lower portion 506 of the mirror layer 502 may have an aluminum fraction that is greater than about 0.6, greater than about 0.8, and/or the like.

As shown in FIG. 5B, when the aluminum content of the upper portion 504 of the mirror layer 502 is oxidized to form the oxide layer 512 (e.g., an oxide aperture), the higher aluminum fraction in the upper portion 504 readily oxidizes to form an oxidized upper portion 514. However, the low aluminum fraction of the middle portion 508 may prevent the middle portion 508 and the lower portion 506 from substantially oxidizing. For example, the aluminum of the middle portion 508 and the lower portion 506 may be substantially unoxidized. In other words, by including the middle portion 508 with a low aluminum fraction, the design of the mirror layer 502 may prevent substantial oxidation in the vertical direction when the upper portion 504 is oxidized. Thus, as shown in FIG. 5B, the oxide layer 512 includes the oxidized upper portion 514 and does not include an oxidized lower portion having a tapered shape, such as the oxidized lower portion 216 of FIG. 2B, despite the high aluminum fraction in the lower portion 506.

As will be appreciated by one of ordinary skill in the art in view of the present disclosure, an oxidation rate in the middle portion 508 may not be zero but may be small enough that the middle portion 508 is not completely oxidized in the vertical direction. Thus, the low aluminum fraction of the middle portion 508 may prevent the middle portion 508 and the lower portion 506 from substantially oxidizing, even though the middle portion 508 may be slightly oxidized. For example, up to the full vertical thickness of the middle portion 508 and the lower portion 506 may be oxidized for positions further from an oxide aperture inner edge than about 3 microns, where the oxide aperture inner edge corresponds to the portion of oxidized upper portion 514 that is closest to the center of the device. In such an example, the middle portion 508 and/or the lower portion 506 may still not be considered substantially oxidized. In other words, as long as less than the full vertical thickness of the middle portion 508 and/or no part of the lower portion 506 within about 3 microns from the oxide aperture inner edge is oxidized, the middle portion 508 and/or the lower portion 506 may still not be considered substantially oxidized.

FIG. 5C is a graph 520 showing a simulated effective index 522, transverse mode profiles 524, and a simulated bandwidth 526 of a laser including the mirror layer 502 of FIG. 5A after oxidation to form the oxide layer 512 of FIG. 5B. As shown by the simulated effective index 522, the narrow shape of the oxidized upper portion 414 provides relatively weak transverse optical guiding and reduces the spectral width to 2 transverse modes as shown by the transverse mode profiles 524. Additionally, the simulated bandwidth 526 of the laser at a current of 7 milliamps is only reduced to 25.6 GHz as compared to the 26.1 GHz of FIG. 2C. Thus, including the middle portion 508 with a low aluminum fraction allows the design to also include a lower portion 506 having a high aluminum fraction that is not oxidized and preserves longitudinal confinement of the optical field, which increases the maximum bandwidth of the laser (e.g., as compared to the maximum bandwidth of a laser having the mirror layer design of FIGS. 4A-4C).

In some embodiments, and as shown in FIG. 5A, the mirror layer 502 may include a first intermediate portion 532 between the upper portion 504 and the middle portion 508, where the first intermediate portion 532 has a graded aluminum fraction that decreases from the higher aluminum fraction adjacent the upper portion 504 to the lower aluminum fraction adjacent the middle portion 508. As also shown in FIG. 5A, the mirror layer 502 may include a second intermediate portion 534 between the middle portion 508 and the lower portion 506, where the second intermediate portion 534 has a graded aluminum fraction that increases from the lower aluminum fraction adjacent the middle portion 508 to the higher aluminum fraction adjacent the lower portion 506.

In some embodiments, and as shown in FIGS. 5A and 5B, the upper portion 504 and the oxide layer 512 may not be aligned with an electric field node. For example, the upper portion 504 and the oxide layer 512 may be positioned with respect to the electric field node to optimize bandwidth of the laser.

In some embodiments, the upper portion 504 may have a thickness along an optical axis, such as the optical axis 120 of the laser 100 of FIG. 1 (e.g., extending in a vertical direction in the orientation shown in FIGS. 5A and 5B) of between about 20 nanometers and 40 nanometers. The middle portion 508 may have a thickness along the optical axis of between about 5 nanometers and 15 nanometers. The lower portion 506 may have a thickness along the optical axis of between about 15 nanometers and 90 nanometers. As shown in FIG. 5B, the oxide layer 512 may form an oxide aperture having a thickness along the optical axis that is substantially uniform in a direction perpendicular to the optical axis.

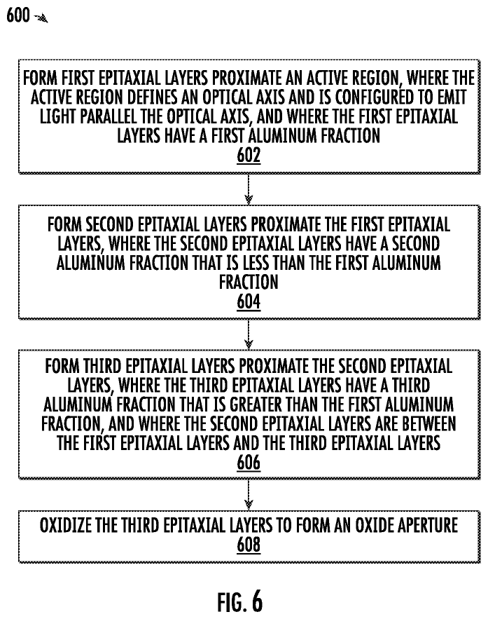

FIG. 6 illustrates a method 600 for manufacturing a laser, in accordance with an embodiment of the invention. In some embodiments, one or more steps from the method 600 may be used to manufacture a laser described herein with respect to FIG. 1 including a mirror layer similar to the mirror layer 502 described herein with respect to FIGS. 5A-5C and having an oxide layer 512 as an oxide aperture.

As shown in block 602, the method 600 may include forming first epitaxial layers proximate an active region, where the active region defines an optical axis and is configured to emit light parallel to an optical axis, and where the first epitaxial layers have a first aluminum fraction. For example, the first epitaxial layers (e.g., of AlGaAs) may be formed on an upper surface of the active region. In some embodiments, the first epitaxial layers may be formed via epitaxial growth using metal-organic chemical vapor deposition (MOCVD), molecular-beam epitaxy (MBE), and/or the like. Additionally, or alternatively, the first epitaxial layers may form a lower portion of a mirror layer similar to the lower portion 506 of the mirror layer 502 shown and described herein with respect to FIGS. 5A-5C.

In some embodiments, the method 600 may include forming the active region. For example, the active region may be formed via epitaxial growth using MOCVD, MBE, and/or the like. In some embodiments, the active region may include, for example, one or more quantum wells formed from quantum well layers. For example, the active region may include GaAs, InGaAs, AlGaAs, GaP, GaAsP, InGaP, AlGaAsP, InGaAlAs, InGaAsP, and/or the like.

As shown in block 604, the method 600 may include forming second epitaxial layers proximate the first epitaxial layers, where the second epitaxial layers have a second aluminum fraction that is less than the first aluminum fraction. In some embodiments, the second epitaxial layers may be formed via epitaxial growth using MOCVD, MBE, and/or the like. For example, the second epitaxial layers (e.g., of AlGaAs) may be formed on an upper surface of the first epitaxial layers. In some embodiments, the second epitaxial layers may form a middle portion of a mirror layer similar to the middle portion 508 of the mirror layer 502 shown and described herein with respect to FIGS. 5A-5C.

As shown in block 606, the method 600 may include forming third epitaxial layers proximate the second epitaxial layers, where the third epitaxial layers have a third aluminum fraction that is greater than the first aluminum fraction, and where the second epitaxial layers are between the first epitaxial layers and the third epitaxial layers. In some embodiments, the third epitaxial layers may be formed via epitaxial growth using MOCVD, MBE, and/or the like. For example, the third epitaxial layers (e.g., of AlGaAs) may be formed on an upper surface of the second epitaxial layers. In some embodiments, the third epitaxial layers may form an upper portion of a mirror layer similar to the upper portion 504 of the mirror layer 502 shown and described herein with respect to FIGS. 5A-5C. Additionally, or alternatively, forming the third epitaxial layers may include forming the third epitaxial layers such that the third epitaxial layers are not aligned with an electric field node.

As shown in block 608, the method 600 may include oxidizing the third epitaxial layers to form an oxide aperture. For example, the third epitaxial layers may be laterally oxidized from an exterior edge of a layer structure including the first epitaxial layers, the second epitaxial layers, and the third epitaxial layers. In some embodiments, the oxide aperture may be similar to the oxide layer 512 shown and described herein with respect to FIGS. 5A-5C.

In some embodiments, the first epitaxial layers, the second epitaxial layers, and the third epitaxial layers may form at least a portion of a mirror layer of a plurality of mirror layers. For example, the first epitaxial layers, the second epitaxial layers, and the third epitaxial layers may form a portion of a mirror layer of a mirror region similar to the first mirror region 106 and/or the second mirror region 108 shown and described herein with respect to FIG. 1.

In some embodiments, the method 600 may include, before forming the second epitaxial layers, selecting the second aluminum fraction to be low enough to prevent oxidation of the second epitaxial layers and the first epitaxial layers while allowing the third epitaxial layers to be oxidized. For example, the method 600 may include selecting the second aluminum fraction to be less than about 0.6.

In some embodiments, the method 600 may include, before forming the first epitaxial layers, selecting the first aluminum fraction to be high enough to longitudinally confine an optical field of the light. For example, the method 600 may include selecting the first aluminum fraction to be greater than 0.6, greater than 0.8, and/or the like.

In some embodiments, the method 600 may include, before forming the second epitaxial layers, forming first intermediate epitaxial layers. In some embodiments, the first intermediate epitaxial layers may be formed via epitaxial growth using MOCVD, MBE, and/or the like. The first intermediate epitaxial layers may be disposed between the first epitaxial layers and the second epitaxial layers, and may have a graded aluminum fraction that decreases from the first aluminum fraction adjacent the first epitaxial layers to the second aluminum fraction adjacent the second epitaxial layers. For example, the first intermediate epitaxial layers may be similar to the second intermediate portion 534 shown and described herein with respect to FIGS. 5A-5C.

In some embodiments, the method 600 may include, before forming the third epitaxial layers, forming second intermediate epitaxial layers. In some embodiments, the second intermediate epitaxial layers may be formed via epitaxial growth using MOCVD, MBE, and/or the like. The second intermediate epitaxial layers may be disposed between the second epitaxial layers and the third epitaxial layers, and may have a graded aluminum fraction that increases from the second aluminum fraction adjacent the second epitaxial layers to the third aluminum fraction adjacent the third epitaxial layers. For example, the second intermediate epitaxial layers may be similar to the first intermediate portion 532 shown and described herein with respect to FIGS. 5A-5C.

Method 600 may include additional embodiments, such as any single embodiment or any combination of embodiments described herein. Although FIG. 6 shows example blocks of a method 600, in some embodiments, the method 600 may include additional blocks, fewer blocks, different blocks, or differently arranged blocks than those depicted in FIG. 6. Additionally, or alternatively, two or more of the blocks of the method 600 may be performed in parallel.

As will be appreciated by one of ordinary skill in the art in view of this disclosure, the present invention may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention and that this invention is not to be limited to the specific constructions and arrangements shown and described, as various other changes, combinations, omissions, modifications and substitutions, in addition to those set forth in the above paragraphs, are possible. In light of this disclosure, those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A laser, comprising:
an active region configured to emit light, wherein the active region defines an optical axis; and
a mirror layer proximate the active region and disposed along the optical axis, wherein the mirror layer comprises:
a first portion proximate the active region having a first aluminum fraction;
a second portion proximate the first portion having a second aluminum fraction that is less than the first aluminum fraction; and
a third portion proximate the second portion having a third aluminum fraction that is greater than the first aluminum fraction,
wherein the second portion is disposed between the first portion and the third portion, and
wherein aluminum in the third portion is oxidized to comprise an oxide aperture.

2. The laser of claim 1, wherein:
the oxide aperture is configured to reduce a spectral width of the light emitted by the active region; and
the first portion of the mirror layer is configured to longitudinally confine an optical field of the light.

3. The laser of claim 1, wherein the mirror layer comprises a first intermediate portion between the first portion and the second portion, wherein the first intermediate portion has a graded aluminum fraction that decreases from the first aluminum fraction adjacent the first portion to the second aluminum fraction adjacent the second portion.

4. The laser of claim 3, wherein the mirror layer comprises a second intermediate portion between the second portion and the third portion, wherein the second intermediate portion has a graded aluminum fraction that increases from the second aluminum fraction adjacent the second portion to the third aluminum fraction adjacent the third portion.

5. The laser of claim 1, wherein aluminum of the first portion and the second portion is substantially unoxidized.

6. The laser of claim 1, wherein the first aluminum fraction is greater than 0.6.

7. The laser of claim 1, wherein the first aluminum fraction is greater than 0.8.

8. The laser of claim 1, wherein the mirror layer comprises AlGaAs.

9. The laser of claim 1, wherein the first portion is not aligned with an electric field node.

10. The laser of claim 1, wherein the mirror layer reduces a spectral width of the light emitted by the active region to less than 5 modes.

11. The laser of claim 1, wherein:
the first portion has a first thickness along the optical axis of between about 30 nanometers and 80 nanometers;
the second portion has a second thickness along the optical axis of between about 5 nanometers and 15 nanometers; and
the third portion has a third thickness along the optical axis of between about 20 nanometers and 40 nanometers.

12. The laser of claim 1, wherein a thickness along the optical axis of the oxide aperture is substantially uniform in a direction perpendicular to the optical axis.

13. The laser of claim 1, wherein the laser is a vertical-cavity surface-emitting laser.

14. The laser of claim 1, wherein the mirror layer is a first mirror layer of a distributed Bragg reflector.

15. The laser of claim 1, wherein the mirror layer comprises a plurality of epitaxial layers, and wherein each of the first portion, the second portion, and the third portion comprises a subset of the plurality of epitaxial layers.

16. A method of manufacturing a laser, the method comprising:
forming first epitaxial layers proximate an active region, wherein the active region defines an optical axis and is configured to emit light parallel to the optical axis, and wherein the first epitaxial layers have a first aluminum fraction;
forming second epitaxial layers proximate the first epitaxial layers, wherein the second epitaxial layers have a second aluminum fraction that is less than the first aluminum fraction;
forming third epitaxial layers proximate the second epitaxial layers, wherein the third epitaxial layers have a third aluminum fraction that is greater than the first aluminum fraction, and wherein the second epitaxial layers are between the first epitaxial layers and the third epitaxial layers; and
oxidizing the third epitaxial layers to form an oxide aperture.

17. The method of claim 16, wherein the first epitaxial layers, the second epitaxial layers, and the third epitaxial layers form at least a portion of a mirror layer of a plurality of mirror layers.

18. The method of claim 16, further comprising, before forming the second epitaxial layers, selecting the second aluminum fraction to be low enough to prevent oxidation of the second epitaxial layers and the first epitaxial layers while oxidizing the third epitaxial layers.

19. The method of claim 16, further comprising, before forming the first epitaxial layers, selecting the first aluminum fraction to be high enough to longitudinally confine an optical field of the light.

20. The method of claim 16, wherein forming the third epitaxial layers comprises forming the third epitaxial layers such that the third epitaxial layers are not aligned with an electric field node.

21. The method of claim 16, further comprising, before forming the second epitaxial layers, forming first intermediate epitaxial layers, wherein the first intermediate epitaxial layers are disposed between the first epitaxial layers and the second epitaxial layers, and wherein the first intermediate epitaxial layers have a graded aluminum fraction that decreases from the first aluminum fraction adjacent the first epitaxial layers to the second aluminum fraction adjacent the second epitaxial layers.

22. The method of claim 21, comprising, before forming the third epitaxial layers, forming second intermediate epitaxial layers, wherein the second intermediate epitaxial layers are disposed between the second epitaxial layers and the third epitaxial layers, and wherein the second intermediate epitaxial layers have a graded aluminum fraction that increases from the second aluminum fraction adjacent the second epitaxial layers to the third aluminum fraction adjacent the third epitaxial layers.
